(19) United States
(12) Patent Application Publication
(10) Pub. No.: US 2009/0302295 A1
(43) Pub. Date: Dec. 10, 2009

(54) Structures & Methods for Combining Carbon Nanotube Array and Organic Materials as a Variable Gap Interposer for Removing Heat from Solid-State Devices

(76) Inventors: Peter Schwartz, Livermore, CA (US); Carlos Dangelo, Los Gatos, CA (US)

Correspondence Address: WILLIAMS, MORGAN & AMERSON, 10333 RICHMOND, SUITE 1100, HOUSTON, TX, 77042, US

(21) Appl. No.: 12/365,377

(22) Filed: Feb. 4, 2009

Related U.S. Application Data
(63) Continuation-in-part of application No. 11/498,408, filed on Aug. 2, 2006.
Application No. 11/498,408 is a continuation of application No. 10/925,824, filed on Aug. 24, 2004, now Pat. No. 7,109,581.
(60) Provisional application No. 61/026,716, filed on Feb. 6, 2008.
(60) Provisional application No. 60/497,849, filed on Aug. 25, 2003.

(51) Int. Cl. H01L 45/00; H01L 21/20

(52) U.S. Cl. 257/2; 438/478; 257/E45.002; 257/E21.09

(57) ABSTRACT

One embodiment involves an article of manufacture that includes: a copper substrate plate with a front surface and a back surface; a blocking (barrier) layer on top of a single surface of the copper substrate; and a thermal interface material (TIM) on top of the single surface of the copper substrate. The thermal interface material comprises: a layer of carbon nanotubes that contains catalyst nanoparticles and, a filler material between and in contact with the carbon nanotubes. The carbon nanotubes are oriented substantially perpendicular to the single surface of the copper substrate and strongly attached to a blocking (barrier) layer. The TIM made of CNT array plus the elastic filler material is interposed between copper plate and the hot surface of a solid-state device. The TIM composite material adjusts to variable gap thickness to make optimal thermal contact area between opposing surfaces. The sandwich structure may include a non-uniform, variable gap TIM that can change during thermal cycles of operation. In some embodiments, the copper substrate plate is configured to be incorporated in a peripheral structure of a heat spreader. In some embodiments, the thermal interface material is on top of both the top and bottom surfaces of the copper substrate plug.

### RELATED APPLICATIONS

This application claims the benefit of U.S. Provisional Application No. 60/909,399, filed May 10, 2007, entitled “Composite Nanotube-Based Structures for Removing Heat From Solid-State Devices and Methods for Making Them”, which is incorporated by reference herein in its entirety.

This application is a continuation-in-part of: (A) U.S. Publication No. US2006/0073712, filed Aug. 17, 2005, entitled “Apparatus and Test Device for the application and measurement of prescribed, predicted and controlled contact pressure on wires”; (B) U.S. patent application Ser. No. 11/498,408, filed Aug. 2, 2006, which is a continuation of U.S. Pat. No. 7,109,581, filed Aug. 24, 2004, which in turn claims the benefit of U.S. Provisional Application No. 60/497,849 filed Aug. 25, 2003; (C) U.S. patent application Ser. No. 11/386,254, filed Mar. 21, 2006, entitled “Apparatus for attaching a cooling structure to an integrated circuit” which in turn claims the benefit of U.S. Provisional Application No. 60/663,225, filed Mar. 21, 2005; (D) U.S. patent application Ser. No. 11/618,441, filed Dec. 29, 2006, entitled “Method and apparatus for the evaluation and improvement of mechanical and thermal properties of CNT/CNF arrays” which in turn claims the benefit of U.S. Provisional Application No. 60/862,664, filed Oct. 24, 2006. All of these applications are incorporated by reference herein in their entirety.

### TECHNICAL FIELD

The disclosed embodiments relate generally to structures and methods for removing heat from integrated circuits and other solid-state devices. More particularly, the disclosed embodiments relate to structures and methods that use carbon nanotubes combined with other materials to remove heat from solid-state devices.

### BACKGROUND

As the speed and density of modern integrated circuits (ICs) increase, the power generated by these chips also increases. The ability to dissipate the heat being generated by IC dies is becoming a serious limitation to advances in IC performance. Similar heat dissipation problems arise in other solid-state devices, such as light emitting diodes (LEDs), lasers, power transistors, RF devices, and solar cells.

Considerable effort has been put into developing materials and structures for use as thermal interface materials, heat spreaders, heat sinks, and other packaging components for ICs and solid-state devices, with limited success.

Thermal interface materials (TIM) are usually sandwiched in a gap between the device and a heat dissipating structure like a heat spreader or heat sink. The combination of flip chip packaging materials with different thermal expansion coefficients, thermal stresses introduced by the packaging assembly process and thermal cycling during operation of solid state devices introduce non-flat and/or dynamically varying-gaps between the device and a heat dissipating structure like a heat spreader or a heat sink.

There is a need for thermal interface materials and structures that are compliant or self-adjusting to make effective thermal contact to the hot surface of the semiconductor die under various conditions of the opposing surfaces of the die and heat spreader with the thermal interface material sandwiched in between. Some of these conditions of the opposing surfaces include: a) non-flat, non-coplanar surfaces with variable gap distances between a non-flat die of a solid state device and a heat spreader or heat sink; b) gaps that vary according to thermal expansion of surfaces of materials with different thermal expansion coefficients; c) die-to-die variation of gap distances arising from assembly process of die, packaging, thermal interface material.

Thus, there remains a need to develop new structures and methods for removing heat from ICs and other solid-state devices that are compatible with current semiconductor packaging technology, provide low thermal resistances, and are low cost.

### SUMMARY OF THE INVENTION

The present invention addresses the problems described in paragraphs above by providing spring-like, compressible carbon nanotube composite thermal interface material structures and methods for removing heat from IC dies and other solid-state devices. Thermal interface materials (TIM) are usually sandwiched in a gap between the IC device and a heat dissipating structure like a heat spreader or heat sink. The disclosed embodiments relate to structures and methods that use carbon nanotube array combined with other materials to remove heat from integrated circuits with non-uniform or dynamic varying gaps between the solid state device (e.g., an integrated circuit) and heat dissipating structures.

One aspect of the invention involves an article of manufacture that includes:

a) a copper substrate plate with a front surface and a back surface; a blocking or barrier layer on top of a single surface of the copper substrate; and a thermal interface elastic material on top of the single surface of the copper substrate. The thermal interface material composite comprises:
b) a layer of carbon nanotube array that contains catalyst nanoparticles and contacts a filler material in between the nanotubes. The carbon nanotubes are oriented substantially perpendicular to the single surface of the copper substrate and are strongly attached to the blocking or barrier layer.
c) One or more layers of a filler material deposited in between the carbon nanotubes array wherein,
1.) The filler material includes a layer with compressible, low Young's Modulus organic material (e.g., family of silicone gel elastomer compounds, acrylates, etc.) embedded interstitially between nanotubes of the array to fill the space with minimum air voids. The composite matter made of nanotube array and the filler has an initial thickness; carbon nanotubes are firmly anchored on the copper substrate and are oriented substantially perpendicular to the surface of the substrate and
2.) The free end tips of CNT array may extend slightly above the surface of the filler material such that when pressed against the hot surface of IC die, the tips buckle or bend sideways to make maximum area-contact and
3.) The compressible composite containing the free end tips of CNT array is elastic, which may be compressed or expanded (spring out) to respond to sandwich gap variations (die “bow” induced during packaging and dynamic gap variation during operation thermal cycling), hence maintaining good thermal contact across the sandwich of variable gap surfaces due to die ‘bow’ (e.g., convexity and/or concavity of the IC die bonded to BGA organic laminate). Additional, dynamic gap variations can arise from change in die bow during thermal cycling when in operation.

Another aspect of the invention involves an article of manufacture as described above that includes a thin layer of phase change material (PCM) above the elastic filler material. In this case, when the composite is brought to a temperature above phase change temperature and compressed with certain pressure against the hot surface of the die, the PCM flows to eliminate air gaps at the interface and may result in a maximum total contact area of all the nanotubes in the array for best (minimum) thermal resistance performance of the TIM.

Another aspect of the invention involves a method that includes placing a filler material between carbon nanotubes in a layer containing carbon nanotubes to form a thermal interface composite material on a front surface of a copper substrate.

Thus, the present invention provides composite carbon nanotube-based structures and methods that more efficiently remove heat from IC dies and other solid-state devices. Such structures and methods are compatible with current semiconductor packaging technology, provide low thermal resistances, and are low cost.

### BRIEF DESCRIPTION OF THE DRAWINGS

For a better understanding of the aforementioned aspects of the invention as well as additional aspects and embodiments thereof, reference should be made to the Description of Embodiments below, in conjunction with the following drawings in which like reference numerals refer to corresponding parts throughout the figures. For clarity, features in some figures are not drawn to scale.

FIG. 1 and FIG. 2 depict prior art situations with uniform or non-uniform gap (known in the art as bond line thickness—BLT of the thermal interface material ‘sandwich’) situations where grease, PCM or soft-metal alloys (e.g., Indium alloys) are deployed for surface ‘compliance’ with thermal expansions inherent in operation of hot solid state devices.

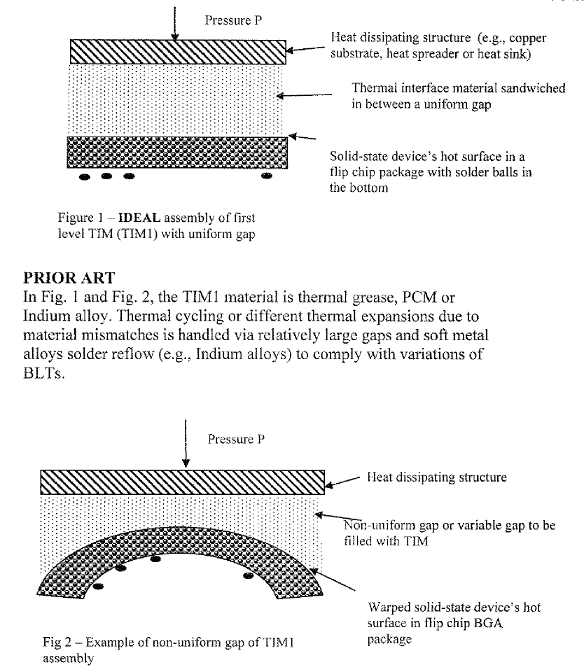

FIG. 3 and FIG. 4 depict a ‘compliant’ thermal interface material CNT composite, which is described in detail below. One or more CNTs in a CNT array may be stretched or compressed according to various shapes to make contact with die hot surface.

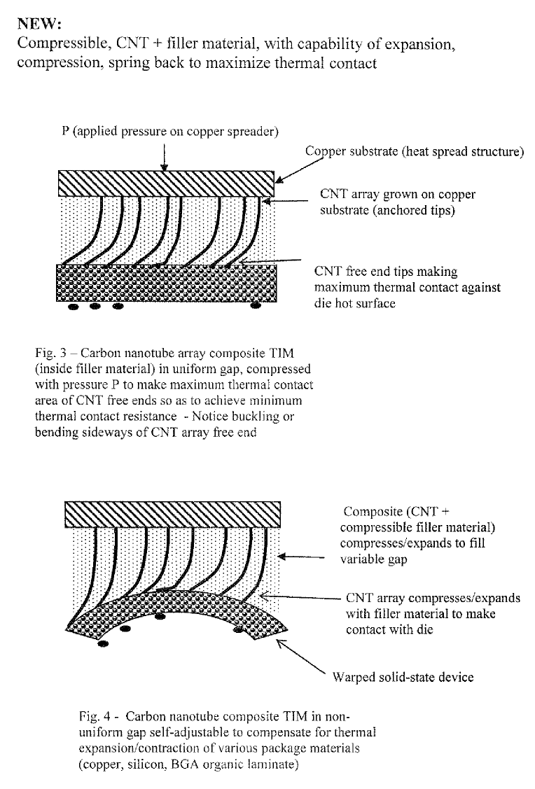

### DESCRIPTION OF EMBODIMENTS

Carbon nanotube-based structures and methods for removing heat from ICs and other solid-state devices are described. As used in the specification and claims, “carbon nanotubes” include carbon nanotubes of varying structural quality, from carbon nanotubes with few defects to carbon nanotubes with many defects (the latter of which are sometimes referred to in the art as “carbon nanofibers”). Thus, as used herein, “carbon nanotubes” include “carbon nanofibers.” Reference will be made to certain embodiments of the invention, examples of which are illustrated in the accompanying drawings. While the invention will be described in conjunction with the embodiments, it will be understood that it is not intended to limit the invention to these particular embodiments alone. On the contrary, the invention is intended to cover alternatives, modifications and equivalents that are within the spirit and scope of the invention as defined by the appended claims.

Moreover, in the following description, numerous specific details are set forth to provide a thorough understanding of the present invention. However, it will be apparent to one of ordinary skill in the art that the invention may be practiced without these particular details. In other instances, methods, procedures, and components that are well known to those of ordinary skill in the art are not described in detail to avoid obscuring aspects of the present invention.

It will be understood that when a layer is referred to as being “on top of” another layer, it can be directly on the other layer or intervening layers may also be present. In contrast, when a layer is referred to as “contacting” another layer, there are no intervening layers present.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The present invention is described below with reference to block diagrams and/or flowchart illustrations of systems, devices, and/or methods according to embodiments of the invention. It should be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

The ‘maximum surface’ thermal contact area with die hot surface is achieved with an embedded CNT array that ‘springs’ up or down due to elasticity of CNT array and of an organic, elastic filler material. In some embodiments the filler material is a low modulus elastomer material (e.g., silicone gel compound or acryl ate) functionalized to provide enough adherence to the walls of the carbon nanotubes so as to achieve the stretching or compressive force on individual CNTS to allow the sandwiched TIM composite material to ‘self-adjust’ to opposing surface as required.

In some embodiments, the CNT arrays may be tailored to conform to mechanical properties in a range of values for: stiffness (CNT array Young's Modulus), for diameters and for aspect ratio of length distribution within min, max values. If the CNT array is too stiff, it will be hard for the majority of nanotubes to make maximum contact, i.e., they do not buckle or bend enough at the free tip end to comply with opposing surface roughness or imperfections. If nanotubes are not stiff enough they might not ‘stand up’ or might collapse into a mat within the filler material. It was discovered that in some embodiments, the required range for CNT array's Young's Modulus (@ room temperature) may lie between 20 GPa to 300 GPa, with 60 GPa being preferred. Correspondingly to these Young's Moduli, a range of aspect ratio (length/diameter) of 1000:1 to 250:1 may be required with 300 being preferred. In some embodiments, the average spacing of individually separated, vertically aligned nanotubes may fall within a certain area density of the CNT array. In general, air pockets either inside the filler matrix or at the die-CNT contact can severely degrade thermal contact given that air thermal conductivity of 0.025 W/m.K is orders of magnitude worse than a typical organic filler material (e.g., 0.20 W/m.K) or individual CNTs (e.g., 500-3000 W/m.K).

In some embodiments, the CNT array organic filler material may be tailored to conform to certain mechanical properties before and after cross linking and curing. Before the cross-linking and curing, the filter material requires adequate viscosity, surface tension and capillary properties to allow for uniform dispersing. After cross linking and curing the organic filler material may have Young's Modulus in a adequate range to adjust to small roughness of the die surface (without air pockets) as well as to adjust (compress/expand) to various BLT gaps when thermal expansion of the opposite surfaces occur. In some embodiments, the Young's Modulus of the organic filler material may fall in the range of KPa to low GPa where 10-100 KPa is preferred.

The experiments performed to determine mechanical compliance performance of the article of manufacture (CNT-based TIM with organic filler material) are described next. In one exemplary situation, the CNT array is filled with organic filler up to the top of CNT array tip with total thickness corresponding to the desired BLT of the end-assembled product.

In some embodiments, the TIM BLT gap is chosen from a typical value between 35-50 um range. The filler material is chosen from one of the following groups: a) a silicone elastomer compound or b) an acryl ate compound (e.g., butyl acryl ate carboxyl-ethyl acryl ate with thermal cross linker). The organic filler material is dispensed into the CNT array to fill to the top of CNT tips. The TIM structure is sandwiched between 2 parallel plates with pressure applied of 130 psi over a contact area of 1.5 cm×1.5 cm typical of an hot IC. The structure is then subjected to 85° C. temperature to simulate operating conditions of heat spreader compressing TIM against the surface of a hot die inside a flip chip package. In one example, the CNT array+filler is submitted to 130 psi of pressure & room temperature is compressed and released. The thermal resistance Rjs between the 2 opposing copper plates is measure during compression to assess changes in thermal contact area.

After the pressure is removed, the TIM+organic filler expands back to a certain BLT thickness and measurements are made to determine the amount of recovery of the compliant TIM. The percentage recovery of BLT thickness, as compared to the original BLT thickness before pressure was applied was measured to be between 91%-100% or the original thickness. The thermal resistance Rjs before and during compression did not change by more than 10%.

TABLE OF RESULTS

| | | | |
|---|---|---|---|
| Organic Filler | Original BLT | TIM's BLT | Thermal |
| | thickness of | thickness | contact area |
| | TIM after | recovery | changes |
| | filler is | after | measured |
| | embedded in | pressure | from Rjs |
| | CNT array | release | changes |
| Silicone | 34 micron | 32 micron or | <10% |
| Elastomer | | 94% recovery | change |
| filler | | from original | |
| (cross linked) | | BLT | |
| Acrylate | 35 micron | 35 micron or | <10% |
| partially | | 100% recovery | change |
| cross linked | | from original | |
| | | BLT | |

In summary, an elastic CNT+filler composite responds to local gap variations to make maximum CNT contact with a hot surface as the surfaces (die, heat spreader or heat sink) change shape (e.g., from flat to concave or convex). BLT gap changes occur due to thermal expansion excursions either during chip temperature operation or as result of chip assembly at much higher temperatures and thermal stresses introduced by assembly of the die+BGA laminate package or due to assembly of the die+BGA+TIM+heat spreader.

1. An article of manufacture, comprising:
a copper substrate plate having a front surface and a back surface; and
a thermal interface layer on top of the single surface of the copper substrate, wherein the thermal interface layer comprises a carbon nanotube array comprising carbon nanotubes each having a fixed end and a free end, each oriented substantially perpendicular to the single surface of the copper substrate and attached to the single surface of the copper substrate at its fixed end, and a filler material between the carbon nanotubes.

2. The article of manufacture of claim 1, wherein the filler material is selected from the group consisting of silicone gel elastomers, acrylates, and mixtures thereof.

3. The article of manufacture of claim 1, wherein the carbon nanotube array has a Young's Modulus at room temperature from about 20 GPa to about 300 GPa.

4. The article of manufacture of claim 1, wherein the carbon nanotube array has an aspect ratio from about 1000:1 to about 250:1.

5. The article of manufacture of claim 1, wherein the filler material has a Young's Modulus at room temperature from about 1 KPa to about 10 GPa.

6. The article of manufacture of claim 1, further comprising a layer of phase change material (PCM) on top of the thermal interface layer, wherein the layer of PCM is thinner than the thermal interface layer.

7. The article of manufacture of claim 1, further comprising a blocking or barrier layer on top of a single surface of the copper substrate.

8. The article of manufacture of claim 1, wherein the article of manufacture has a bond line thickness (BLT) from about 35 μm to about 50 μm.

9. The article of manufacture of claim 8, wherein the article of manufacture has a BLT after being subjected to a pressure of 130 psi and released to atmospheric pressure (post-compression BLT) between 90% and 100% of its BLT before being subjected to the pressure of 130 psi.

10. The article of manufacture of claim 9, wherein the article of manufacture has a thermal resistance (Rjs) when being subjected to a pressure of 130 psi and released to atmospheric pressure (compression Rjs) between 90% and 110% of its thermal resistance before being subjected to the pressure of 130 psi.

11. The article of manufacture of claim 1, wherein the free ends of substantially all the carbon nanotubes extend above the filler material.

12. A method of manufacturing an article, comprising:
attaching a plurality of carbon nanotubes, each carbon nanotube having a first end and a second end, at its first end to a front surface of a copper substrate, to form a carbon nanotube array; and
placing a filler material between the carbon nanotubes in the carbon nanotube array, to form a thermal interface layer on top of the copper substrate.

13. The method of claim 12, wherein placing the filler material results in the free ends of substantially all the carbon nanotubes extending above the filler material.

14. The method of claim 12, further comprising placing a layer of phase change material (PCM) on top of the thermal interface layer, wherein the layer of PCM is thinner than the thermal interface layer.
